(19) United States
(12) Patent Application Publication
(10) Pub. No.: US 2019/0074370 A1
(43) Pub. Date: Mar. 7, 2019

(54) SEMICONDUCTOR DEVICE PRIMARILY MADE OF NITRIDE SEMICONDUCTOR MATERIALS AND PROCESS OF FORMING THE SAME

(71) Applicant: SUMITOMO ELECTRIC INDUSTRIES, LTD., Osaka (JP)

(72) Inventors: Kenta SUGAWARA, Osaka (JP); Kazutaka INOUE, Osaka (JP)

(73) Assignee: SUMITOMO ELECTRIC INDUSTRIES, LTD., Osaka (JP)

(21) Appl. No.: 16/122,463

(22) Filed: Sep. 5, 2018

(30) Foreign Application Priority Data
Sep. 6, 2017 (JP) 2017-171036

(51) Int. Cl. H01L 29/778; H01L 29/40; H01L 29/20; H01L 29/66; H01L 29/417; H01L 29/423; H01L 21/02; H01L 21/768

(52) U.S. Cl. CPC H01L 29/7787; H01L 29/402; H01L 29/2003; H01L 21/76832; H01L 29/41725; H01L 29/42364; H01L 21/02274; H01L 29/66462

(57) ABSTRACT

A semiconductor device made of primarily nitride semiconductor materials is disclosed. The semiconductor device includes a substrate; a semiconductor stack on the substrate; electrodes of a gate, a source, and a drain each provided on the semiconductor stack, where the gate electrode contains nickel (Ni); a Si compound covering surfaces of the semiconductor stack; an aluminum oxide (Al₂O₃) film covering the gate electrode exposed from the Si compound; and another Si compound covering the Al₂O₃ film and the Si compound exposed from the Al₂O₃ film. A feature of the semiconductor device of the invention is that the Al₂O₃ film exposes the Si compound at least between the gate electrode and the drain electrode.

### CROSS REFERENCE TO RELATED APPLICATION

The present application is based on and claims the benefit of priority of Japanese Patent Application No. 2017-171036, filed on Sep. 6, 2017, the entire content of which is incorporated herein by reference.

### BACKGROUND OF INVENTION

### 1. Field of Invention

The present invention relates to a semiconductor device type of high electron mobility transistor (HEMT), in particular, the invention relates to a HEMT primarily made of nitride semiconductor materials and a process of forming the HEMT.

### 2. Related Background Arts

A transistor primarily made of nitride semiconductor materials typically gallium nitride (GaN) has become popular in the field. In particular, a transistor type of HEMT may operate in high speed at high power because of a wide bandgap characteristic inherently attributed to nitride semiconductor materials. Such a HEMT provides a channel layer made of GaN and a barrier layer made of aluminum gallium nitride (AlGaN).

A Japanese Patent Application laid open No. JP-2017-059621A has disclosed a HEMT made of nitride semiconductor materials. The HEMT disclosed therein provides nitride semiconductor layers epitaxially grown on a substrate and electrodes of a source, a drain, and a gate. The HEMT further provides a first insulating film made of silicon nitride (SiN) that covers the nitride semiconductor layers and the electrodes, where the electrodes are in contact with the nitride semiconductor layers through respective openings formed in the first insulating film. The HEMT also provides a second insulating film made of aluminum oxide (Al₂O₃) that covers the gate electrode and the first insulating film. Another Japanese Patent Application laid open No. JP-2009-059946A has also disclosed a HEMT that provides dual insulating films, one of which is in contact with a nitride semiconductor layer and made of tantalum oxide (Ta₂O₅), while another insulating film covers the former insulating film and is made of silicon nitride (SiN).

Thus, a HEMT made of nitride semiconductor materials often provides the dual insulating films on the nitride semiconductor layer, where the insulating films is often made of material containing silicon (Si), such as SiN above described, silicon oxide (SiO₂), and/or silicon oxy-nitride (SiON). On the other hand, a HEMT made of nitride semiconductor materials often provides a gate electrode including nickel (Ni) to make a Schottky contact against the nitride semiconductor layer. However, nickel atoms in the gate electrode easily combine with silicon (Si) atoms contained in an insulating film and form various types of nickel silicide (NiSi, NiSi₂, and so on) that are stable and hard to uncouple the bonding between Ni and Si. Because a nickel silicide shows substantial conductance, an electrical isolation between the gate electrode and a field plate, which is often provided in the HEMT apart from the gate electrode by interposing the insulating film and electrically connected with the source electrode, becomes degraded.

One solution is to cover the gate electrode with an aluminum oxide (Al₂O₃) film because a bond between aluminum (Al) and oxide (O) is more stable compared with a bond between Ni and Al, and/or between Ni and O in the Al₂O₃ film, which means that Ni atoms are hard to inter-diffuse into the Al₂O₃ film, that is, the Al₂O₃ film may show effective function to stop the diffusion of the Ni atoms into an insulating film containing silicon (Si). However, an Al₂O₃ film, when it is stacked on the gate electrode and an insulating film containing Si, typically, silicon nitride (SiN), leaves a subject to increase a current collapse of a nitride semiconductor device.

### SUMMARY OF INVENTION

One aspect of the present invention relates to a semiconductor device that is primarily made of nitride semiconductor materials. The semiconductor device of the invention comprises a substrate, a semiconductor stack provided on the substrate, electrodes of a gate, a source, and a drain each provided on the semiconductor stack, a Si compound that covers surfaces of the semiconductor stack between the gate electrode and the drain electrode and between the gate electrode and the source electrode, an aluminum oxide (Al₂O₃) film that covers the gate electrode exposed from the Si compound; and another Si compound that covers the Al₂O₃ film and the Si compound exposed from the Al₂O₃ film. The source electrode and the drain electrode sandwiches the gate electrode therebetween, while, the gate electrode includes nickel (Ni). The Si compound and the other Si compound contain silicon (Si) atoms. A feature of the semiconductor device of the present invention is that the Al₂O₃ film exposes a surface of the Si compound at least between the gate electrode and the drain electrode.

Another aspect of the present invention relates to a process of forming a semiconductor device primarily made of nitride semiconductor materials. The process comprises steps of: (a) epitaxially growing a semiconductor stack on a substrate; (b) forming electrodes of a source, a gate, and a drain by steps of: (b-1) deposing a first insulating film made of silicon nitride (SiN) on the semiconductor stack by a low pressure chemical vapor deposition (LPCVD) technique, (b-2) forming the source electrode and the drain electrode so as to be in direct contact with the semiconductor stack through respective openings formed in the first insulating film, (b-3) covering the source electrode, the drain electrode, and the first insulating film with a second insulating film made of silicon nitride (SiN) formed by a plasma-assisted chemical vapor deposition (p-CVD) technique, the first insulating film and the second insulating film constituting the Si compound, and (b-4) forming a gate electrode so as to be in direct contact with the semiconductor stack through an opening formed in the Si compound, the gate electrode including nickel (Ni); (c) covering the gate electrode and the Si compound by an aluminum oxide (Al₂O₃) film; (d) partially removing the Al₂O₃ film at least between the gate electrode and a drain electrode; and (e) depositing another Si compound so as to cover the Al₂O₃ film and the Si compound exposed from the Al₂O₃ film, the another Si compound containing Si atoms. A feature of the process according to the present invention is that the Al₂O₃ film fully covers the gate electrode exposed from the Si compound but partially removed so as to expose the Si compound at least between the gate electrode and the drain electrode.

### BRIEF DESCRIPTION OF THE DRAWINGS

The foregoing and other purposes, aspects and advantages will be better understood from the following detailed description of a preferred embodiment of the invention with reference to the drawings, in which:

FIG. 1 is a plan view showing a high electron mobility transistor (HEMT) according to the present invention;

FIG. 2 is a cross sectional view of the HEMT taken along the line II-II indicated in FIG. 1;

FIG. 3 is a cross sectional view of the HEMT that magnifies a portion around the gate electrode;

FIG. 4 is a plan view of the Al₂O₃ film denoted as hatched areas;

FIG. 5A to FIG. 5C are cross sectional views of the HEMT at respective steps of a manufacturing process thereof;

FIG. 6A to FIG. 6C are cross sectional views of the HEMT at respective steps of the manufacturing process thereof subsequent to that shown in FIG. 5C;

FIG. 7A and FIG. 7B are cross sectional views of the HEMT at respective steps of the manufacturing process thereof subsequent to that shown in FIG. 6C;

FIG. 8A and FIG. 8B are cross sectional views of conventional HEMTs comparable to the HEMT shown in FIG. 2;

FIG. 9A and FIG. 9B each compare drain current characteristics measured in a pulsed mode with those measured in a DC mode for the conventional HEMTs shown in FIG. 8A and FIG. 8B;

FIG. 10A and FIG. 10B schematically illustrate band diagrams of the conventional HEMTs;

FIG. 11 is a cross sectional view of another HEMT according to the second embodiment of the present invention; and

FIG. 12 magnifies a portion around the gate electrode of the HEMT shown in FIG. 11.

### DESCRIPTION OF EMBODIMENTS

Next, some embodiments according to the present invention will be described as referring to drawings. The present invention is not restricted to those embodiments and includes all changes and modifications defined in claims attached and equivalents thereof. Also, in the description of the drawings, numerals or symbols same with or similar to each other will refer to elements same with or similar to each other without duplicated explanations.

### First Embodiment

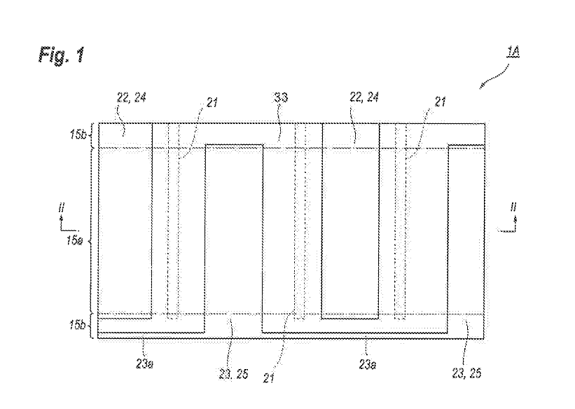

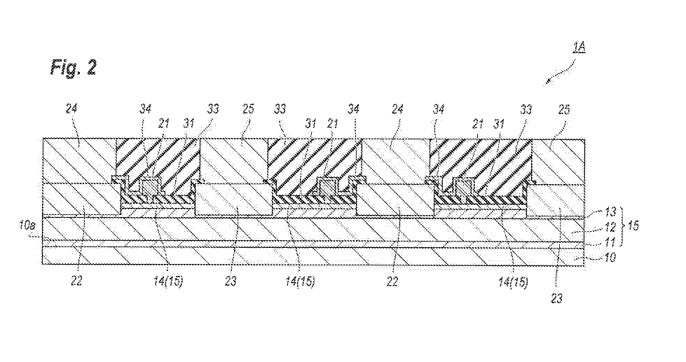

FIG. 1 is a plan view showing a high electron mobility transistor (HEMT) 1A according to the present invention, and FIG. 2 is a cross sectional view of the HEMT 1A taken along the line II-II indicated in FIG. 1. The HEMT 1A of the present embodiment includes a substrate 10, a semiconductor stack 15 including nitride semiconductor materials, and sets of electrodes of a gate 21, a source 22, and a drain 23. The HEMT 1A may further provide a silicon (Si) compound 31 containing silicon (Si), another Si compound 33 also containing Si, and an aluminum oxide (Al₂O₃) film 34.

The substrate 10, which provides a top surface 10a on which the semiconductor stack 15 is epitaxially grown, may be made of semi-insulating material, for instance, silicon carbide (SiC). The top surface 10a of the substrate may have a crystal orientation of (0001).

The semiconductor stack 15 may include a nucleus forming layer 11 made of aluminum nitride (AlN), a channel layer 12 made of gallium nitride (GaN), a barrier layer 13, and a cap layer 14 made of GaN, where those layers, 11 to 14, are epitaxially grown on the top surface 10a of the substrate 10 in this order. The semiconductor stack 15 may be divided into two regions as shown in FIG. 1, namely, an active region 15a and an inactive region 15b surrounding the active region 15a, where the latter region 15b may be formed by implanting argon (Ar) ions therein. The inactive region 15b thus formed has an insulating characteristic. The gate electrodes 21, the source electrodes 22, and the drain electrodes 23 are each electrically connected in the inactive region 15a.

The AlN nucleus forming layer 11, which is epitaxially grown on the top surface 10a of the substrate 10, may operate as a seed layer for the GaN channel layer 12. The AlN nucleus forming layer 11 may have a thickness of 5 to 50 nm, specifically 20 nm in the present embodiment. The GaN channel layer 12, which is epitaxially grown on the AlN nucleus forming layer 11, may operate as a carrier transporting layer. Because a GaN shows lesser wettability against a SiC, which means a GaN layer is hard to be directly grown on a SiC, the GaN channel layer 12 is provided on the SiC substrate interposing the AlN nucleus forming layer 11. The GaN channel layer 12 may have a thickness of 0.3 to 2.0 μm, specifically, around 1.0 μm in the present embodiment.

The barrier layer 13, which is epitaxially grown on the GaN channel layer 12, has bandgap energy greater than that of the GaN channel layer 12 and operates as an electron supplying layer. The barrier layer 13 may be made of n-type aluminum gallium nitride (AlGaN) or an n-type indium aluminum nitride (InAlN). The barrier layer 13 causes stresses against the GaN channel layer 12 because of a discrepancy in a lattice constant thereof against that of the GaN channel layer 12, which induces charges by the piezo effect. Thus, a two-dimensional electron gas is induced in the GaN channel layer 12 at the interface against the barrier layer 13, which becomes the channel for transporting the electrons in the HEMT 1A. The barrier layer 13 may have a thickness of 5 to 30 nm, specifically 20 nm in the present embodiment. The barrier layer 13 may have an aluminum composition of 10 to 35% when the barrier layer 13 is made of AlGaN, where the aluminum composition is preferably 20% in the present embodiment. The barrier layer 13 may have indium composition of 10 to 20%, specifically, 18% when the barrier layer 13 is made of InAlN.

The GaN cap layer 14, which is epitaxially grown on the barrier layer 13, may prevent aluminum (Al) from being oxidized and have a thickness of 1 to 5 nm, specifically, 5 nm in the present embodiment.

The source electrode 22 and the drain electrode 23, as shown in FIG. 1, extend along one direction and disposed alternately along another direction perpendicular to the one direction. The gate electrodes 21 extend also along the one direction and disposed between the source electrode 22 and the drain electrode 23. The source electrodes 22 are electrically connected to each other at a source bar provided on the inactive region 15b. Also, the drain electrodes 23 are electrically connected to each other by a drain interconnection 23a provided on the inactive region 15b. The gate electrodes 21 are also connected to each other through still another interconnection provided on the inactive region 15b.

The source electrode 22 and the drain electrode 23, which are ohmic electrodes formed by alloying stacked metals of titanium (Ti) and aluminum (Al), may be provided on the barrier layer 13 and in contact thereto. Other stacked metals of tantalum (Ta) and aluminum (Al) may be also applicable as the ohmic electrodes, 22 and 23. Although the HEMT 1A of the present embodiment provides the ohmic electrodes, 22 and 23, in contact with the barrier layer 13 as described above, the ohmic electrodes, 22 and 23, may be in contact with the GaN cap layer 14 without forming recesses in the cap layer 14 and the barrier layer 13.

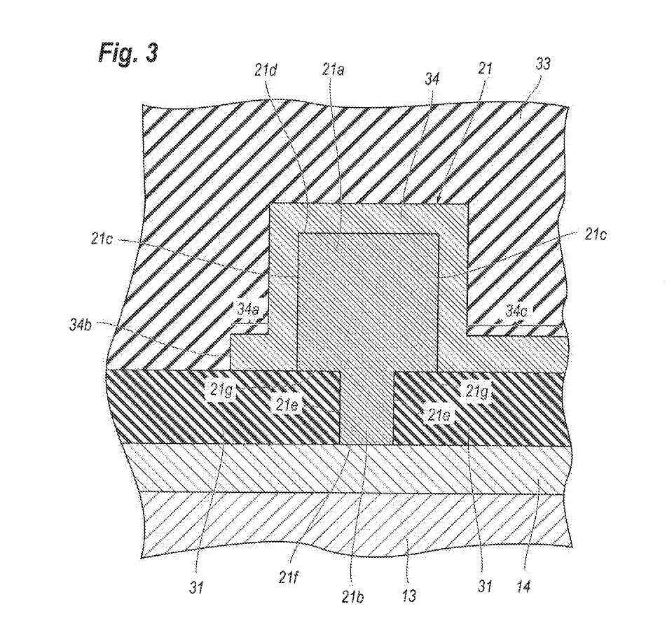

The gate electrode 21, which is formed on the GaN cap layer 14 and in contact therewith, is a type of Schottky electrode having stacked metals of nickel (Ni) and gold (Au), where the Ni layer is in contact with the GaN cap layer 14. FIG. 3 is a cross sectional view magnifying a portion around the gate electrode 21. As shown in FIG. 3, the gate electrode 21 has a T-shaped cross section including a first portion 21a corresponding to a horizontal bar of the T-character and a second portion 21b corresponding to a vertical bar of the T-character. The first portion 21a provides a pair of sides 21c and a top 21d connecting the sides 21c. The second portion 21b also provides a pair of sides 21e and a bottom 21f that is in contact with the surface of the semiconductor stack 15 and connects the sides 21e. The second portion 21b has a width between the sides 21e that is shorter than a width between the sides 21c in the first portion 21a. The first portion 21a forms an overhung in the respective sides of the second portion 21b, where the former width of the second portion 21b corresponds to the gate length of the HEMT 1A, which is, for instance, 200 nm in the present embodiment.

The Si compound 31, which is an electrically insulating film, passivates, or protects, the semiconductor stack 15 exposed between the gate electrodes 21, the source electrode 22, and the drain electrode 23. The Si compound 31 may be made of silicon nitride (SiN) with an opening within which the second portion 21b of the gate electrode 21 is buried, while, the first portion 21a of the gate electrode 21 is provided on the surface of the Si compound 31. The Si compound 31 preferably has a thickness substantially equal to a height of the first portion 21a of the gate electrode 21, which is preferably greater than 10 nm but smaller than 100 nm, where the HEMT 1A of the present embodiment has the thickness around 40 nm.

The aluminum oxide (Al₂O₃) film 34 covers the gate electrode 21 in portions exposed from the Si compound 31. Specifically, the Al₂O₃ film 34 is in contact with the sides 21c and the top 21d of the first portion 21a of the gate electrode 21, and partially covers the Si compound 31 in a portion 34a adjacent to the gate electrode 21 that extends from the side 21c toward the drain electrode 23. The portion 34a preferably has a width narrower than 200 nm, which is far smaller than a distance from the gate electrode 21 to the drain electrode 23. The HEMT 1A of the present embodiment provides the portion 34a with a width of 50 nm; while, a distance from the gate electrode 21 to the drain electrode 23 is preferably form 0.5 to 5.0 μm.

The Al₂O₃ film 34 may further provide another portion 34c extending from the gate electrode 21 to the source electrode 22 and covers the Si compound 31 between the gate electrode 21 and the source electrode 22. Thus, the Si compound 31 in a side of the source electrode 22 is fully covered with the Al₂O₃ film 34. The Al₂O₃ film 34 preferably has a thickness greater than 10 nm, or further preferably greater than 20 nm, but smaller than 100 nm.

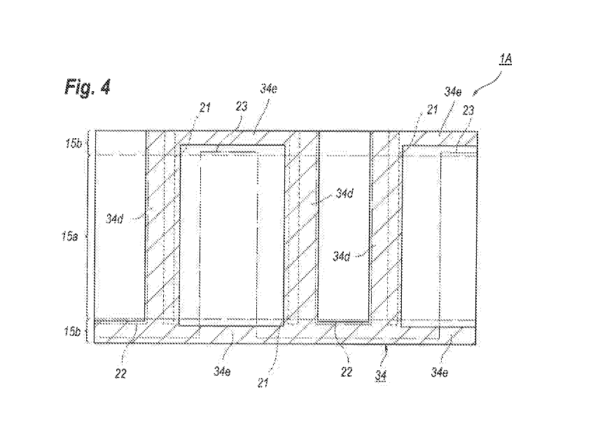

FIG. 4 is a plan view of the Al₂O₃ film 34, where hatched areas correspond to the Al₂O₃ film 34. As shown in FIG. 4, the Al₂O₃ film 34 includes portions 34d extending along the gate electrode 21 in active regions 15a and portions 34e connecting the former portions 34d in inactive regions 15b. Those portions, 34d and 34e, form areas into which the drain electrodes 23 are disposed.

Referring to FIG. 2 and FIG. 3 again, the other Si compound 33, which is an insulating film, covers the Al₂O₃ film 34 and the Si compound 31. The other Si compound 33 may be made of silicon nitride (SiN) and preferably have a thickness greater than 500 nm, where the HEMT 1A of the present embodiment provides the other Si compound 33 with a thickness of 1000 nm. The other Si compound 33 provides opening on the source electrode 22 and the drain electrode 23, into which respective interconnections, 24 and 25, are filled to extract and supply currents to the source electrode 22 and/or the drain electrode 23. Those interconnections, 24 and 25, may be made of stacked metals of titanium (Ti) and gold (Au), where titanium (Ti) is in contact with the source electrode 21 and the drain electrode 22.

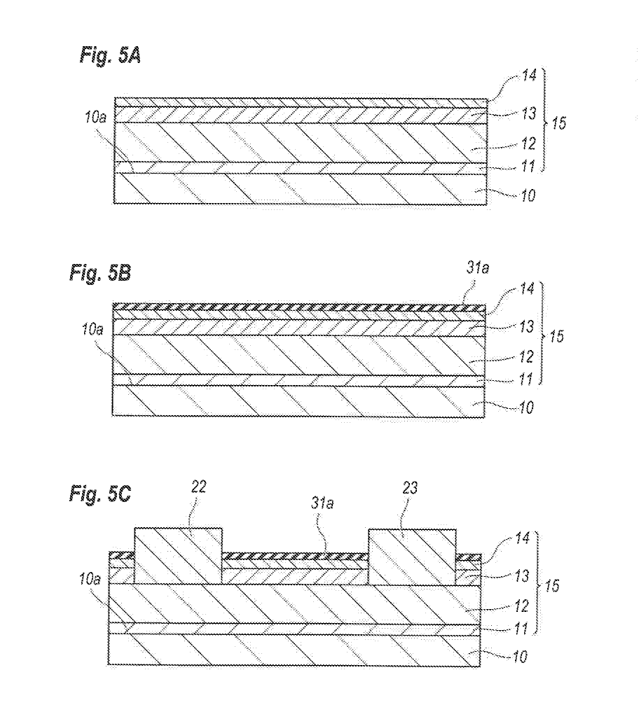

Next, a process of forming the HEMT 1A according to an embodiment of the present invention will be described as referring to FIG. 5A to FIG. 7B each showing cross sectional views of the HEMT 1A at respective steps of the process.

First, as shown in FIG. 5A, the process sequentially grows an AlN nucleus forming layer 11, a GaN channel layer 12, a barrier layer 13 and a GaN cap layer on a substrate 10 in this order, where those epitaxial layers, 11 to 14, form a semiconductor stack 15. The epitaxial growth may be carried out by, for instance, the metal organic chemical vapor deposition (MOCVD) technique using tri-methyl-gallium (TMG), tri-methyl-aluminum (TMA), tri-methyl-indium (TMI), and ammonia (NH₃) for source materials of Ga, Al, In, and N, respectively.

Thereafter, as shown in FIG. 5B, the process deposits a first insulating film 31a on the semiconductor stack 15 by a technique of the plasma assisted chemical vapor deposition (p-CVD) and/or the low pressure chemical vapor deposition (LPCVD). The former technique (p-CVD) may set a deposition temperature to be around 300° C. and use mono-silane (SiH₄) and ammonia (NH₃) as source materials for silicon (Si) and nitrogen (N). While, the latter technique (LPCVD) may set a deposition temperature thereof to be around 800° C. and use di-chloro-silane (SiCl₂ H₂) or mono-silane (SiH₄) for Si and NH₃ for N.

Thereafter, as shown in FIG. 5C, the process forms a source electrode 22 and a drain electrode 23 on the semiconductor stack 15. Specifically, portions of the first insulating film 31a, those of the GaN cap layer 14, and those of the barrier layer 13 are etched, where those portions correspond to areas of the source electrode 22 and the drain electrode 23. Sequential processes of the photolithography and the subsequent reactive ion etching (RIE) may be used for etching those portions. In an alternative, only the first insulating film 31a is partially etched as leaving the GaN cap layer 14 and the barrier layer 13. Subsequent to the partial etching, the process may stack metal films so as to fill the partially etched first insulating film 31a, the GaN cap layer 14 and the barrier layer 13, where the metal films contain titanium (Ti) with a thickness around 30 nm and aluminum (Al) with a thickness around 300 nm. Physical deposition technique, such as the metal evaporation and/or the metal sputtering, may be used for stacking the metal films. After the deposition of the metal films, the process alloys the metal films at, for instance, 500° C., or preferably higher than 550° C.

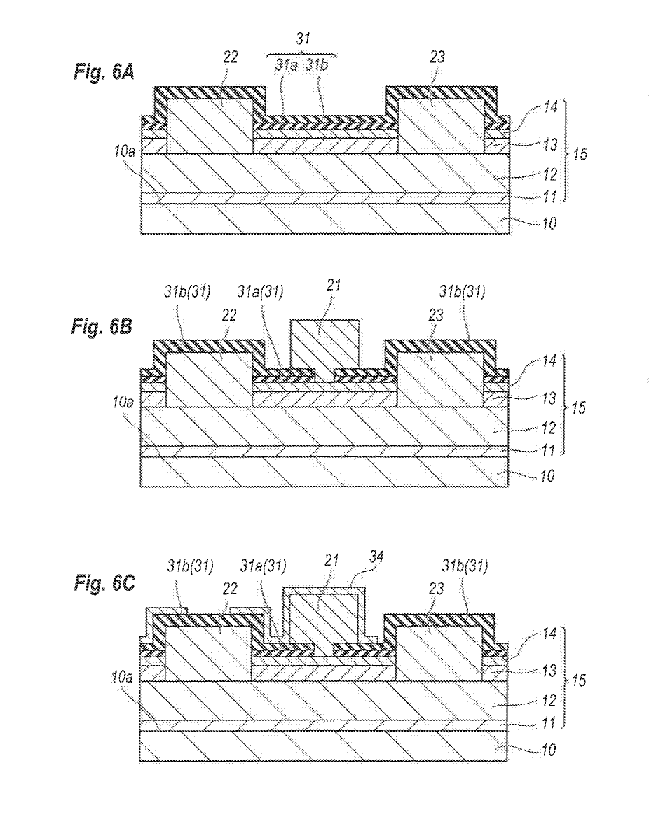

Thereafter, as shown in FIG. 6A, the first insulating film 31a, the source electrode 22, and the drain electrode 23 are covered with a second insulating film 31b. The p-CVD technique may be used for depositing the second insulating film 31b. The first insulating film 31a and the second insulating film 31b constitute the Si compound 31 in the present invention.

Thereafter, as shown in FIG. 6B, the process forms a gate electrode 21 between the source electrode 22 and the drain electrode 23. Specifically, partially removing the second insulating film 31b and the first insulating film 31a to form a gate window in the Si compound 31, the surface of the cap layer 14 may be exposed within the gate window. Subsequent to the formation of the gate window, the process may deposit gate metal with a configuration of stacked metals of nickel (Ni) by a thickness around 50 nm and gold (Au) by a thickness around 400 nm, where nickel (Ni) is in contact with the GaN cap layer 14 as a Schottky metal. The gate electrode 21 is in contact with the GaN cap layer 14 within the gate window and overlaps on the Si compound 31 in respective sides of the gate window.

Thereafter, as shown in FIG. 6C, the gate electrode 21 and the Si compound 31 are covered with an insulating film 34 made of aluminum oxide (Al₂O₃). The Al₂O₃ film 34, which may be deposited by, for instance, the atomic layer deposition (ALD) technique at a temperature around 150° C. and using source materials of TMA for aluminum (Al) and water (H₂O), ozone (O₃), or oxygen plasma for oxygen (O). Then, the sequential process of the photolithography and the subsequent RIE may partially remove the Al₂O₃ film in portions on the drain electrode 23 and a region between the gate electrode 21 and the drain electrode 23 using a reactive gas containing chlorine (Cl), such as BCl₃, Cl₂, and so on. An opening in the Al₂O₃ film 34 is left on the source electrode 22.

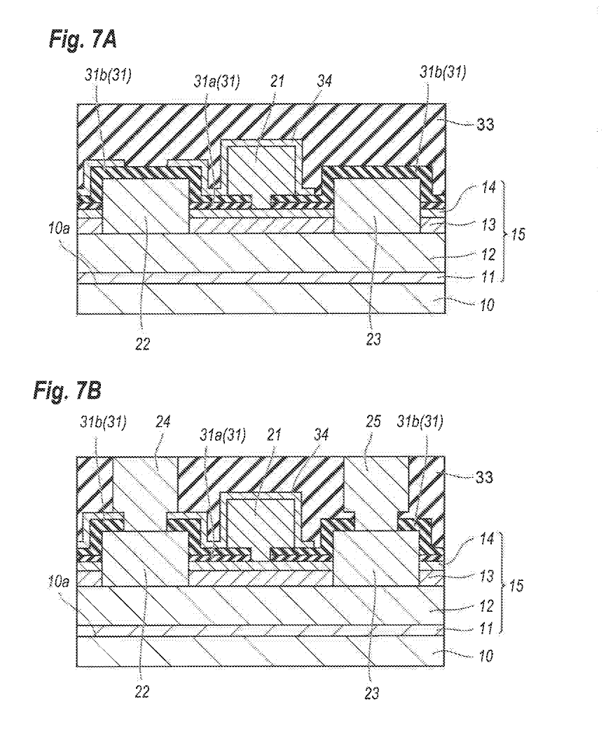

Thereafter, as shown in FIG. 7A, the Al₂O₃ film 34 and the Si compound 31 exposed from the Al₂O₃ film 34 are covered with another Si compound 33. The other Si compound 33 may be deposited by the p-CVD technique at a deposition temperature around 300° C. and source materials of mono-silane (SiH₄) and ammonia (NH₃) for silicon (Si) and nitrogen (N), respectively.

Finally, as shown in FIG. 7B, a source interconnection 24 and a drain interconnection 25 are formed so as to be in contact with the source electrode 22 and the drain electrode 23, respectively. Specifically, a sequential process of the photolithography and the subsequent RIE may form openings in the other Si compound 33 and the Si compound 31. Because the Al₂O₃ film 34 provides the opening on the source electrode 22, the RIE using a reactive gas containing fluorine (F) may form the openings in the Si compound 31 on the source electrode 22 and the drain electrode 23. The source electrode 22 and the drain electrode 23 in respective top surfaces thereof exposed within the openings. Selective plating of gold (Au) with a thickness of, for instance, at least 1 μm within the opening and on the other Si compound 33 so as to be in contact with the source electrode 22 and the drain electrode 23, the process of forming the HEMT 1A according to the present embodiment may be completed.

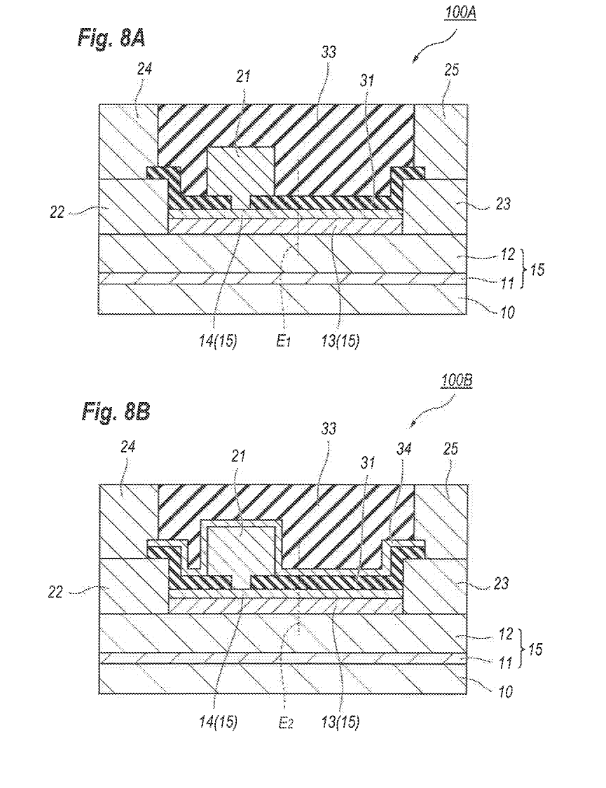

Advantages of the HEMT 1A according to the present embodiment will be described as comparing with conventional HEMTs, 100A and 100B, whose cross sectional views are shown in FIG. 8A and FIG. 8B, respectively. The conventional HEMT 100A provides no Al₂O₃ film on the Si compound 31, while the other conventional HEMT 100B provides an Al₂O₃ film not only a region between the gate electrode 21 and the source electrode 22 but also in the region between the gate electrode 21 and the drain electrode 23, that is, the Al₂O₃ film 34 in the conventional HEMT 100B fully covers the Si compound 31.

The gate electrode 21 of the present embodiment and those of the conventional HEMTs, 100A and 100B, provide the stacked metals including nickel (Ni) and gold (Au). However, nickel (Ni) inherently shows a characteristic to easily form silicide material combined with silicon (Si) atoms contained in the Si compounds surrounding the gate electrode 21, where those silicide materials show substantial conductance. Accordingly, the other Si compound 33 in which nickel silicide is induced reduces the resistivity thereof, which may cause a short circuit between the gate electrode 21 and, for instance, a field plate often formed on the other Si compound 33. Also, the gate electrode 21 itself increases the resistivity thereof because of the extraction of nickel (Ni) atoms.

The conventional HEMT 100B shown in FIG. 8B covers the gate electrode 21 and the Si compound 31 with another insulating film 34 made of aluminum oxide (Al₂O₃). A bond between aluminum (Al) and oxide (O) is more stable compared with the bond between nickel (Ni) and aluminum (Al) or Ni and oxygen (O) in the Al₂O₃ film 34; accordingly, the Al₂O₃ film may effectively become a barrier for diffusing nickel (Ni) into the Si compound 33. However, the Al₂O₃ film fully covering the Si compound 31 may deform the band diagram of the nitride semiconductor stack 15 due to a difference in the thermal expansion co-efficient between the Al₂O₃ film 34 and the Si compound 31, which causes a greater stress between two insulating films, 31 and 34. Specifically, an increased stress may raise the level of the conduction band at the surface of the nitride semiconductor stack 15, which exposes traps ordinary hidden under the Fermi level E_{F} and resultantly increases the current collapse.

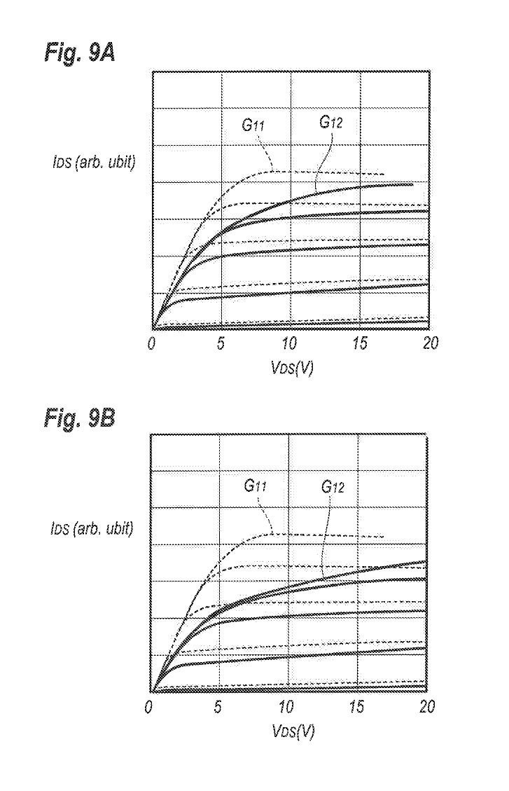

FIG. 9A and FIG. 9B show drain current characteristics of the HEMTs, 100A and 100B, respectively, where the drain current IDS was dynamically measured as the drain bias V_{DS} was supplied in pulses. Specifically, the drain current IDs was measured at 5 μs after the HEMTs, 100A and 100B, are turned on from a turned off status at which the gate bias V_{GS} and the drain bias V_{DS} are set to be V_{GS}=−5V and V_{DS}=50V, respectively. Dotted lines G₁₁ were measure in a steady mode denoted as the DC mode, that is, the drain current IDs was measure under conditions of the steady drain bias V_{DS} and the steady gate bias V_{GS}; while, solid lines G₁₂ show the drain current IDs measured in the pulsed mode described above.

Comparing the behaviors G₁₂ measured in the pulsed mode, the current collapse degrades in FIG. 9B compared with that shown in FIG. 9A; that is, the Al₂O₃ film 34 fully covering the Si compound degrades the current collapse, where the current collapse may be determined by the reduction of the drain current after the bias stress is released compared with that without receiving any bias stresses. Denoting I_{D1} and I_{D2} are the drain currents measured in the DC mode and that in the pulsed mode after the bias stress is released; the current collapse may be indexed by (I_{D2}−I_{D1})/I_{D1}. That is, the current collapse of −30% means that the drain current IDs decreases by 30% compared with no bias stresses. Referring to FIG. 9A and FIG. 9B, the current collapse shown in FIG. 9A is about −20% but that in FIG. 9B increases to around −30%. Thus, the Al₂O₃ film fully covering the Si compound 31 may increase the current collapse.

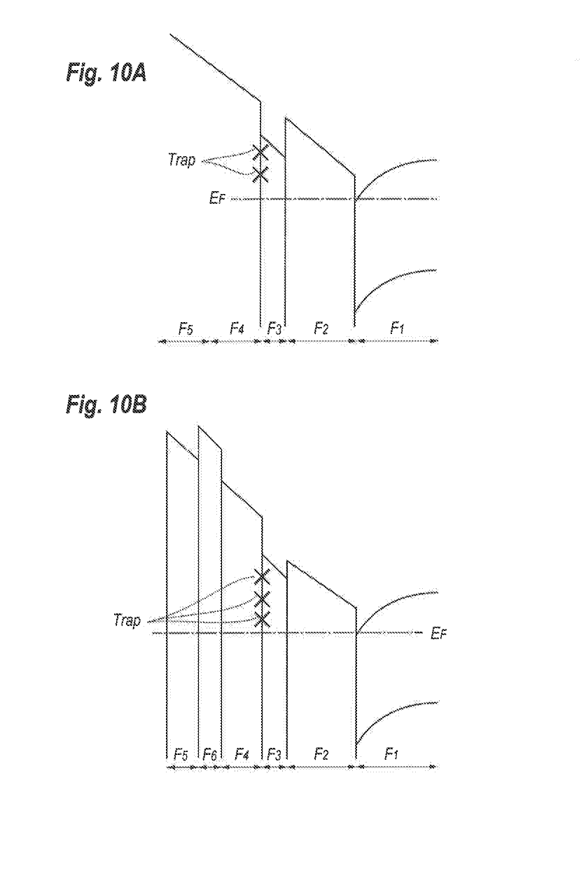

FIG. 10A and FIG. 10B schematically illustrate band diagrams of the films, 31 to 34, and the semiconductor stack 15, where they are taken along the line E₁ indicated in FIG. 8A and E₂ indicated in FIG. 8B. Regions F₁ to F₆ shown in FIG. 10A and FIG. 10B correspond to the GaN channel layer 12, the barrier layer 13, the GaN cap layer 14, the Si compound 31, the other Si compound 33, and the Al₂O₃ film 34, respectively. Also, FIG. 10A and FIG. 10B show trap levels by a symbol “Trap” that may capture carriers, namely, electrons traveling in the 2DEG in the GaN channel layer 12; and the Fermi level by the symbol E_{F}. Referring to FIG. 10B, the conduction band diagram in the cap layer 14 and the barrier layer 13 are raised due to the existence of the Al₂O₃ film 34, which exposes trap levels in the GaN cap layer 14, and sometimes in the barrier layer 13, ordinarily hidden under the Fermi level E_{F}. Exposed trap levels may capture electrons traveling in the 2DEG in the GaN channel layer 12 and resultantly increases the current collapse.

The HEMT 1A of the present embodiment provides the Al₂O₃ film 34 that covers the gate electrode 21 exposed from the Si compound 31 but reveals the Si compound 31 between the gate electrode 21 and the drain electrode 23, which may moderate the stress caused in the Al₂O₃ film 34 and the Si compound 31, resultantly the current collapse. The Al₂O₃ film 34 covering the gate electrode 21 may effectively behave as a diffusion barrier for nickel (Ni) atoms invading into the other Si compound 33, which may effectively prevent the field plate provided on the other Si compound 33 from making a short circuit to the gate electrode 21 and the increase of the resistivity of the gate electrode 21 due to the extraction nickel (Ni) atoms.

Table below summarizes advantages and disadvantages of insulating films covering the gate electrode 21 and the Si compound 31. As described, the HEMT 100A without any Al₂O₃ film, which corresponds to the first conventional one in Table, shows a good current collapse but inferior reliability due to the inter-diffusion of nickel (Ni) atoms from the gate electrode 21 into the other Si compound 33. The HEMT 100B shown in FIG. 8B, which corresponds to the second conventional one, may enhance the reliability because of the existence of the Al₂O₃ film 34 covering the gate electrode 21 but degrades the current collapse because of the increased stress between the Al₂O₃ film 34 and the Si compound 31, which increases the substantial traps that may capture electrons running in the 2DEG in the GaN channel layer 12. The HEMT 1A of the present embodiment, the Al₂O₃ film 34 covers the gate electrode 21 but exposes the Si compound 31 between the gate electrode 21 and the drain electrode 23, which not only effectively prevents the diffusion of Ni atoms into the other Si compound 33 but releases the stress caused between the Si compound 31 and the Al₂O₃ film 34; thus, effectively suppress the increase of the current collapse.

| type | insulating films | current collapse | Ni diffusion |
|---|---|---|---|
| conventional 1 | SiN/SiN | good | bad |
| conventional 2 | Al₂O₃/SiN | bad | good |
| embodiment | partial Al₂O₃/SiN | preferable | good |

The Si compound 31 may cover the gate electrode 21 in the sides 21e of the second portion 21b thereof; while, the Al₂O₃ film 34 may cover the sides 21c and the top 21d of the first portion 21a of the gate electrode 21; which effectively prevents the diffusion of Ni atoms into the other Si compound 33. The Al₂O₃ film 34 of the present embodiment may have a thickness at least 10 nm.

Also, the Al₂O₃ film 34 of the present embodiment may provide the portion 34a extending from the side 21c in a drain side of the gate electrode 21 toward the drain electrode 23, where the portion 34a preferably has a width of 200 nm at most. Thus, the Al₂O₃ film 34 may widen an area for exposing the surface of the Si compound 31 between the gate electrode 21 and the drain electrode 23, which may effectively suppress the current collapse.

The semiconductor stack 15 of the present embodiment may include the barrier layer 13 made of indium aluminum nitride (InAlN) substituting from that made of AlGaN. The InAlN barrier layer 13 possibly strengthens the effect originated from the stress caused between the Si compound 31 and the Al₂O₃ film 34 because the InAlN barrier 13 weakens the stress caused between the barrier layer 13 and the GaN cap layer 14 due to a lattice miss-matching therebetween. Accordingly, when the semiconductor stack 15 having the InAlN barrier 13 between the gate electrode 21 and the drain electrode 23 is fully covered with the Al₂O₃ film 34, the current collapse is remarkably strengthened. The configuration of the Al₂O₃ film 34 of the present invention where the Al₂O₃ film exposes the Si compound 31, or does not cover the Si compound 31, between the gate electrode 21 and the drain electrode 23 becomes particularly effective for the semiconductor stack 15 including an InAlN barrier layer 13.

### Second Embodiment

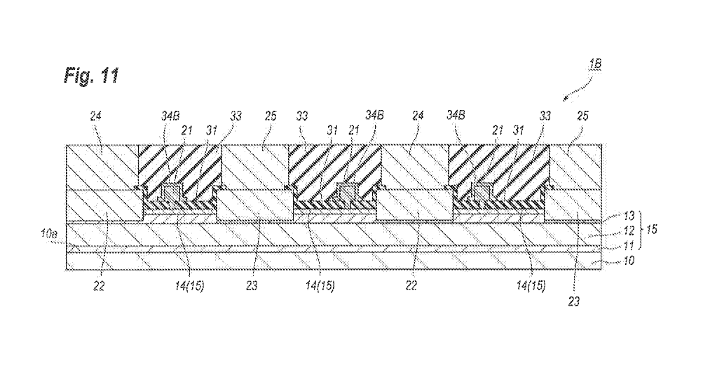

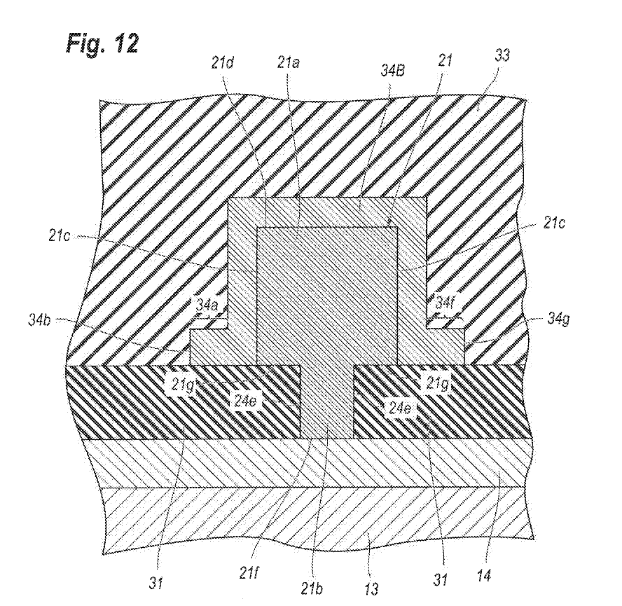

FIG. 11 is a cross sectional view of another HEMT 1B according to the second embodiment of the present invention, and FIG. 12 magnifies a portion around the gate electrode 21 of the HEMT 1B shown in FIG. 11. The HEMT 1B of the second embodiment has a feature, which is distinguishable from the HEMT 1A of the first embodiment, that the Al₂O₃ film 34B exposes the Si compound 31 not only between the gate electrode 21 and the drain electrode 23 but between the gate electrode 21 and the source electrode 22.

Specifically, the Al₂O₃ film 34B of the second embodiment covers the gate electrode 21 exposed from the Si compound 31; that is, the Al₂O₃ film 34B provides a portion 34f extending from the side 21c toward the source electrode 22 in addition to a portion that covers the first portion 21a of the gate electrode 21, namely, the top 21d and the sides 21c of the gate electrode 21 and the portion 34a extending toward the drain electrode 23 from the other side 21c. The portion 34f also has a width of 200 nm at most measured from the side 21c of the gate electrode 21, which is smaller or far smaller than a distance from the gate electrode 21 to the source electrode 22. The HEMT 1B of the second embodiment has the portion 34f with the width of 50 nm. Thus, the Si compound 31 is exposed between the gate electrode 21, exactly, the edge 34g of the Al₂O₃ film 34, and the source electrode, whose width is preferably 100 to 1000 nm.

The Al₂O₃ film 34B of the present embodiment may be formed by the process shown in FIG. 6C. That is, the process partially and concurrently removes the Al₂O₃ film 34 in respective sides of the gate electrode 21. The configuration of the Al₂O₃ film 34B of the present embodiment may be further effective to suppress the current collapse because the stress caused between the Al₂O₃ film 34B and the Si compound 31 may be weakened also between the gate electrode 21 and the source electrode 22.

In the foregoing detailed description, the process of the present invention has been described with reference to specific exemplary embodiments thereof. However, it would be evident that various modifications and changes may be made thereto without departing from the broader spirit and scope of the present invention. For instance, the embodiments concentrate on an electron device type of high electron mobility transistor (HEMT), but the process of the present invention may be applicable to another device except for a field effect transistor (FET). Also, the HEMT provides the SiC substrate 10 but a HEMT of the present invention may provide another substrate as far as a substrate may epitaxially grow semiconductor layers thereon. The HEMTs of the present invention provide Si compounds, 31 and 33, made of silicon nitride (SiN) but a HEMT of the present invention may provide another type of Si compound, such as silicon oxide (SiO₂), silicon oxy-nitride (SiON), and so on. Accordingly, the present specification and figures are to be regarded as illustrative rather than restrictive.

We claim:

1. A semiconductor device made of primarily nitride semiconductor materials, the semiconductor device comprising:
a substrate;
a semiconductor stack provided on the substrate, the semiconductor stack including nitride semiconductor layers;
electrodes of a gate, a source, and a drain each provided on the semiconductor stack, the source electrode and the drain electrode sandwiching the gate electrode therebetween, the gate electrode including nickel (Ni);
a Si compound that covers surfaces of the semiconductor stack between the gate electrode and the drain electrode and between the gate electrode and the source electrode, the Si compound containing silicon (Si) atoms;
an aluminum oxide (Al₂O₃) film that covers the gate electrode exposed from the Si compound; and
another Si compound that covers the Al₂O₃ film and the Si compound exposed from the Al₂O₃ film, the another Si compound containing Si atoms,
wherein the Al₂O₃ film exposes a surface of the Si compound at least between the gate electrode and the drain electrode.

2. The semiconductor device according to claim 1,
wherein the Al₂O₃ film further exposes a surface of the Si compound between the gate electrode and the source electrode.

3. The semiconductor device according to claim 1,
wherein the gate electrode has a T-shaped cross section having a first portion corresponding to a horizontal bar of the T-shape and a second portion corresponding to a vertical bar of the T-shape,
wherein the second portion is within an opening provided in the Si compound and in contact with the surface of the semiconductor stack, and the first portion is provided on the Si compound, and
wherein the Al₂O₃ film covers the first portion of the gate electrode.

4. The semiconductor device according to claim 1,
wherein the Al₂O₃ film provides a portion extending on the Si compound toward the drain electrode, the portion having a width of 200 nm at most.

5. The semiconductor device according to claim 1,
further comprising a field plate provided on the another Si compound, the field plate overlapping with the gate electrode but shifted toward the drain electrode.

6. The semiconductor device according to claim 1,
wherein the Al₂O₃ film has a thickness of at least 10 nm.

7. The semiconductor device according to claim 1,
wherein the semiconductor stack includes a channel layer made of gallium nitride (GaN) and a barrier layer made of aluminum gallium nitride (AlGaN).

8. The semiconductor device according to claim 1,
wherein the semiconductor stack includes a channel layer made of GaN and a barrier layer made of indium aluminum nitride (InAlN).

9. The semiconductor device according to claim 1,
wherein the semiconductor stack includes a cap layer in a top thereof, the cap layer being made of GaN.

10. The semiconductor device according to claim 1,
wherein the Si compound includes a first insulating film in contact with the semiconductor stack and a second insulating film provided on the first insulating film, the first insulating film and the second insulating film being made of silicon nitride (SiN), and
wherein the second insulating film covers the source electrode and the drain electrode.

11. A process of forming a semiconductor device, comprising steps of:
epitaxially growing a semiconductor stack on a substrate;
forming electrodes of a source, a gate, and a drain by steps of:
deposing a first insulating film made of silicon nitride (SiN) on the semiconductor stack by a low pressure chemical vapor deposition (LPCVD) technique,
forming the source electrode and the drain electrode so as to be in direct contact with the semiconductor stack through respective openings formed in the first insulating film,
covering the source electrode, the drain electrode, and the first insulating film by a second insulating film made of silicon nitride (SiN) formed by a plasma-assisted chemical vapor deposition (p-CVD) technique, the first insulating film and the second insulating film constituting the Si compound, and
forming a gate electrode so as to be in direct contact with the semiconductor stack through an opening formed in the Si compound, the gate electrode including nickel (Ni);
covering the gate electrode and the Si compound by an aluminum oxide (Al₂O₃) film;
partially removing the Al₂O₃ film at least between the gate electrode and a drain electrode; and
depositing another Si compound so as to cover the Al₂O₃ film and the Si compound exposed from the Al₂O₃ film, the another Si compound containing Si atoms.

12. The process according to claim 11,
wherein the step of partially removing the Al₂O₃ film leaves the Al₂O₃ film at most 200 nm from the gate electrode toward the drain electrode.

13. The process according to claim 11,
wherein the step of partially removing the Al₂O₃ film further removes the Al₂O₃ film between the gate electrode and the source electrode.

14. The process according to claim 13,
wherein the step of partially removing the Al₂O₃ film leaves the Al₂O₃ film at most 200 nm from the gate electrode toward the source electrode.

15. The process according to claim 11,
further comprising a step of forming a field plate on the another Si compound such that the filed plate is overlapped with the gate electrode but shifted toward the drain electrode.
